(19) United States
(12) Patent Application Publication
(10) Pub. No.: US 2025/0369089 A1
(43) Pub. Date: Dec. 4, 2025

(54) DEPOSITION MASK

(71) Applicant: Samsung Display Co., LTD., Yongin-si (KR)

(72) Inventors: Min Gu KIM, Yongin-si (KR); Hyo Yul YOON, Yongin-si (KR); Kyoung Ah LEE, Yongin-si (KR); Jin Woo LEE, Yongin-si (KR)

(21) Appl. No.: 18/961,146

(22) Filed: Nov. 26, 2024

(30) Foreign Application Priority Data
Jun. 4, 2024 (KR) 10-2024-0073117

(51) Int. Cl. C23C 14/04; H10K 71/16

(52) U.S. Cl. CPC C23C 14/042; H10K 71/166

(57) ABSTRACT

A deposition mask for depositing a pattern on a display panel includes an in-cell area and an out-cell area around the in-cell area, a first composite layer in the in-cell area and the out-cell area, and a support layer on a lower surface of the first composite layer in the out-cell area. The first composite layer includes one or more tensile layers including a tensile material that has a stress greater than 0, and one or more compressive layers including a compressive material that has a stress less than 0. Each layer has a characteristic value measured by multiplying a stress of each layer by a corresponding thickness of each layer. A ratio between a sum of the characteristic values of the one or more tensile layers and a sum of characteristic values of the one or more compressive layers is within a range of about 0.5 to about 1.

### CROSS-REFERENCE TO RELATED APPLICATION

The present application claims priority to and the benefit of Korean Patent Application No. 10-2024-0073117, filed on Jun. 4, 2024, in the Korean Intellectual Property Office, the entire content (e.g., amount) of which is incorporated herein by reference.

### BACKGROUND

### 1. Field

Embodiments of the present disclosure relate to a deposition mask.

### 2. Description of the Related Art

An organic light-emitting display device may include an anode arranged on a substrate, a cathode, and an organic emission layer interposed between the anode and the cathode. The organic emission layer may be formed using a deposition mask.

The above information disclosed in this Background section is only for enhancement of understanding of the background of the disclosure and therefore it may contain information that does not constitute prior art.

### SUMMARY

Aspects of one or more embodiments of the present disclosure are direct toward a deposition mask of which a warpage (or deformation) is minimized or reduced.

Additional aspects will be set forth in part in the description which follows and, in part, will be apparent from the description, or may be learned by practice of the presented embodiments of the disclosure.

A deposition mask for depositing a pattern on a display panel according to one or more embodiments of the present disclosure includes an in-cell area and an out-cell area around the in-cell area, wherein the deposition mask has an opening in the in-cell area, a first composite layer in the in-cell area and the out-cell area, and a support layer on a lower surface of the first composite layer in the out-cell area, wherein the first composite layer includes one or more tensile layers including a tensile material that has a stress greater than 0, and includes one or more compressive layers including a compressive material that has a stress less than 0, wherein each layer of the one or more tensile layers and the one or more compressive layers has a characteristic value measured by multiplying a stress of each layer by a corresponding thickness of each layer, and a ratio between a total sum of the characteristic values of the one or more tensile layers of the first composite layer and a total sum of the characteristic values of the one or more compressive layers of the first composite layer is within a range of about 0.5 to about 1.

In one or more embodiments, the tensile material may include at least one selected from among silicon nitride, molybdenum, and aluminum, and the compressive material may include at least one selected from among silicon oxide and tungsten.

In one or more embodiments, the total sum of the characteristic values of the one or more tensile layers may be equal to the total sum of the characteristic values of the one or more compressive layers.

In one or more embodiments, the first composite layer may include a first layer and a second layer between the first layer and the support layer, wherein the one or more tensile layers may include one of the first layer or the second layer, and the one or more compressive layers may include the other of the first layer or the second layer, a ratio between a characteristic value of a first layer and a characteristic value of the second layer may be within a range of about 0.5 to about 1, the characteristic value of the first layer may be measured by multiplying a stress of the first layer by a thickness of the first layer, and the characteristic value of the second layer may be measured by multiplying a stress of the second layer by a thickness of the second layer.

In one or more embodiments, one of the first layer or the second layer may include silicon nitride, the other of the first layer or the second layer may include silicon oxide, and the thickness of one of the first layer or the second layer may be about 4.5 times to about 18 times the thickness of the other of the first layer or the second layer.

In one or more embodiments, the thickness of one of the first layer or the second layer may be within a range of about 1 μm to about 1.4 μm, and the thickness of the other of the first layer or the second layer may be within a range of about 0.05 μm to about 0.31 μm.

In one or more embodiments, the thickness of one of the first layer or the second layer may be within a range of about 1 μm to about 1.4 μm, and the thickness of the other of the first layer or the second layer may be within a range of about 0.11 μm to about 0.15 μm.

In one or more embodiments, the first composite layer may include a first layer, a second layer between the first layer and the support layer, and a third layer on the first layer, wherein the one or more tensile layers may include the second layer and the third layer, and the one or more compressive layers may include the first layer, a ratio between a total sum of characteristic values of the second layer and the third layer and a characteristic value of the first layer may be within a range of about 0.5 to about 1, the characteristic value of the first layer may be measured by multiplying a stress of the first layer by a thickness of the first layer, the characteristic value of the second layer may be measured by multiplying a stress of the second layer by a thickness of the second layer, and the characteristic value of the third layer may be measured by multiplying a stress of the third layer by a thickness of the third layer.

In one or more embodiments, the second layer and the third layer may include silicon nitride, and the first layer includes silicon oxide, and a total thickness of the second layer and the third layer may be about 4.5 times to about 18 times the thickness of the first layer.

1 In one or more embodiments, the thickness of each of the second layer and the third layer may be within a range of about 0.5 μm to about 0.7 μm, and the thickness of the first layer may be within a range of about 0.1 μm to about 0.17 μm.

In one or more embodiments, the deposition mask may further include a second composite layer on a lower surface of the support layer, and the first composite layer and the second composite layer may have a structure that is symmetrical with respect to the support layer.

In one or more embodiments, the first composite layer may include a first layer and a second layer between the first layer and the support layer, the second composite layer may include a fourth layer and a third layer between the fourth layer and the support layer, the one or more tensile layers may include one of the first layer or the second layer and one of the third layer or the fourth layer, the one or more compressive layers may include the other of the first layer or the second layer, and the other of the third layer or the fourth layer, a total sum of characteristic values of the first layer and the second layer may be equal to a total sum of characteristic values of the third layer and the fourth layer, the characteristic value of the first layer may be measured by multiplying a stress of the first layer by a thickness of the first layer, the characteristic value of the second layer may be measured by multiplying a stress of the second layer by a thickness of the second layer, the characteristic value of the third layer may be measured by multiplying a stress of the third layer by a thickness of the third layer, and the characteristic value of the fourth layer may be measured by multiplying a stress of the fourth layer by a thickness of the fourth layer.

In one or more embodiments, the first layer and the fourth layer may include the same material, and the second layer and the third layer may include the same material.

In one or more embodiments, the thickness of the first layer may be equal to the thickness of the fourth layer, and the thickness of the second layer may be equal to the thickness of the third layer.

A deposition mask for depositing a pattern on a display panel according to one or more embodiments of the present disclosure includes an in-cell area and an out-cell area around the in-cell area, a support layer in the out-cell area, a first composite layer on the support layer and including a plurality of layers, wherein one of the layers is in the in-cell area, and a second composite layer below the support layer and including a plurality of layers, wherein, in the in-cell area, the first composite layer has an opening corresponding to a pixel of the display panel, and the first composite layer and the second composite layer have a structure that is symmetrical with respect to the support layer.

In one or more embodiments, some of the plurality of layers of each of the first composite layer and the second composite layer may include a tensile material having a stress greater than 0, and others of the plurality of layers of each of the first composite layer and the second composite layer may include a compressive material having a stress less than 0.

In one or more embodiments, the tensile material may include at least one selected from among silicon nitride, molybdenum, and aluminum, and the compressive material may include at least one selected from among silicon oxide and tungsten.

In one or more embodiments, the first composite layer may include a first layer and a second layer between the first layer and the support layer, the second composite layer may include a fourth layer and a third layer between the fourth layer and the support layer, a sum of a characteristic value of the first layer and a characteristic value of the second layer may be equal to a sum of a characteristic value of the third layer and a characteristic value of the fourth layer, the characteristic value of the first layer may be measured by multiplying a stress of the first layer by a thickness of the first layer, the characteristic value of the second layer may be measured by multiplying a stress of the second layer by a thickness of the second layer, the characteristic value of the third layer may be measured by multiplying a stress of the third layer by a thickness of the third layer, and the characteristic value of the fourth layer may be measured by multiplying a stress of the fourth layer by a thickness of the fourth layer.

In one or more embodiments, the first layer and the fourth layer may include the same material, and the second layer and the third layer may include the same material.

In one or more embodiments, the thickness of the first layer may be equal to the thickness of the fourth layer, and the thickness of the second layer may be equal to the thickness of the third layer.

Specific details of one or more embodiments are included in the detailed description and drawings.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of present disclosure. In the drawings:

FIG. 1 is an exploded, schematic perspective view illustrating a deposition apparatus according to one or more embodiments of the present disclosure.

FIG. 2 is a cross-sectional view illustrating the deposition apparatus of FIG. 1, according to one or more embodiments of the present disclosure.

FIG. 3 is a plan view illustrating a mask according to one or more embodiments of the present disclosure.

FIG. 4 is an enlarged view of an in-cell area of a mask, according to one or more embodiments of the present disclosure.

FIG. 5 is a cross-sectional view taken along the line I-I′ of FIG. 3, according to one or more embodiments of the present disclosure.

FIGS. 6 and 7 are each a cross-sectional view for describing warpage of a mask, according to one or more embodiments of the present disclosure.

FIG. 8 is a graph showing warpage according to a thickness of a layer included in the mask of FIG. 5.

FIG. 9 is a cross-sectional view illustrating the mask of FIG. 3, according to one or more embodiments of the present disclosure.

FIG. 10 is a cross-sectional view illustrating the mask of FIG. 3, according to one or more embodiments of the present disclosure.

FIG. 11 is a cross-sectional view illustrating the mask of FIG. 3, according to one or more embodiments of the present disclosure.

FIG. 12 is a cross-sectional view illustrating the mask of FIG. 3, according to one or more embodiments of the present disclosure.

FIG. 13 is a cross-sectional view illustrating the mask of FIG. 3, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof. “At least any one of X, Y, and Z” and “at least any one selected from the group consisting of X, Y, and Z” may be construed as each of X, Y, and Z and/or a (e.g., any suitable) combination of two or more of X, Y, and Z (for example, XYZ, XYY, YZ, and ZZ).

As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element, such as an area, layer, film, region or portion, is referred to as being “on” or “coupled to” another element, it can be directly on or coupled to the other element, or one or more intervening elements may be present. In addition, it will also be understood that when an element is referred to as being “between” two elements, it can be the only element between the two elements, or one or more intervening elements may also be present.

As used herein, the singular forms “a,” “an” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

Various embodiments are described with reference to drawings that schematically illustrate ideal embodiments. Accordingly, it will be expected that the shapes may vary depending, for example, on tolerances and/or manufacturing techniques. Accordingly, one or more embodiments disclosed herein should not be construed as limited to the specific shapes shown herein, but should be construed to include deviations in shapes that result from, for instance, manufacturing. As such, the shapes shown in the drawings may not depict the actual shapes of regions of the device, and the present embodiments are not limited thereto.

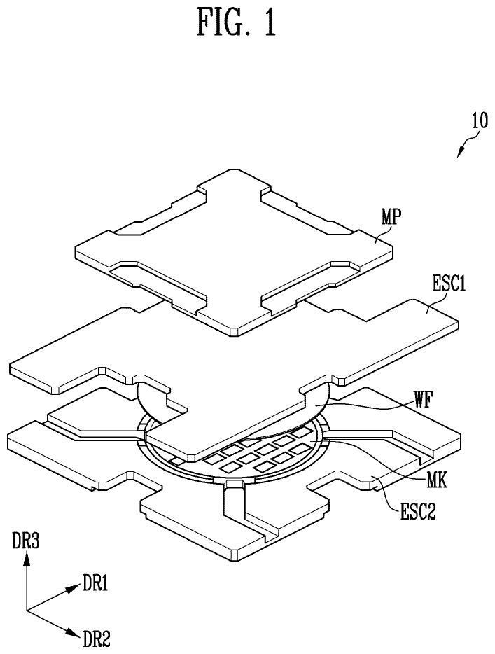

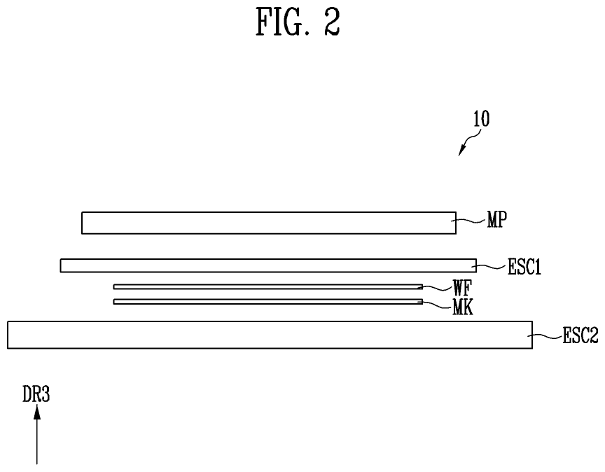

FIG. 1 is a schematic perspective view illustrating a deposition apparatus according to one or more embodiments of the present disclosure. FIG. 2 is a cross-sectional view illustrating the deposition apparatus of FIG. 1, according to one or more embodiments of the present disclosure. A mask MK may be parallel to a plane defined by a first direction DR1 and a second direction DR2. A normal (e.g., perpendicular) direction of the plane may be defined as a third direction DR3. In one or more embodiments, the illustrated first to third directions DR1, DR2, and DR3 are merely examples defined for convenience of description, and the first to third directions DR1, DR2, and DR3 may be relative concepts and may be converted into different directions.

Referring to FIGS. 1 and 2, a deposition apparatus 10 may include the mask MK, a first electrostatic chuck ESC1, a second electrostatic chuck ESC2, and a magnetic plate MP. The deposition apparatus 10 may further include a chamber and a deposition source. The mask MK, the first electrostatic chuck ESC1, the second electrostatic chuck ESC2, the magnetic plate MP, and the deposition source may be arranged in a space in the chamber.

The deposition apparatus 10 may deposit a deposition material on a wafer WF (or a substrate). The deposition material may be formed on the wafer WF in the chamber. The deposition material may include an organic material, but the present disclosure is not limited thereto. For example, the deposition material may include a material for forming an emission layer of an organic light-emitting element to be manufactured. The deposition material is stored in a deposition source. For example, the deposition source may be positioned below the mask MK (and the second electrostatic chuck ESC2), and the deposition material may be sprayed toward the mask MK and the wafer WF.

The wafer WF may be a mother substrate to be deposited, or a mother substrate. A display panel circuit (or a pixel circuit, for example, a transistor or an anode) may be formed on the wafer WF. When a deposition process is performed, the wafer WF may be arranged between the first electrostatic chuck ESC1 and the mask MK.

The wafer WF may be fixed by the first electrostatic chuck ESC1. The first electrostatic chuck ESC1 may fix the wafer WF using an electrostatic force and may bring the wafer WF into close contact with the mask MK. The first electrostatic chuck ESC1 may be coupled to the wafer WF to prevent or limit the wafer WF from moving during alignment of a deposition process and during deposition of a deposition material.

The mask MK (or deposition mask) may be arranged below the wafer WF. For example, the mask MK may be arranged between the wafer WF and the deposition source, and the deposition material may be patterned on one surface of the wafer WF through the mask MK (or an opening of the mask MK). For example, the mask MK may be a shadow mask made of a silicon wafer or a fine metal mask. The mask MK may be fixed or supported by the second electrostatic chuck ESC2.

The magnetic plate MP may be arranged on the first electrostatic chuck ESC1 (and the wafer WF). The magnetic plate MP may be a sample holder for fixing the movement of the wafer WF. For example, the magnetic plate MP may generate a magnetic field to pull the mask MK, and thus the mask MK and the wafer WF may be brought into close contact with each other. Accordingly, during a deposition process, a risk of lifting between the mask MK and the wafer WF may be reduced, and a shadow effect generated during the deposition process may be improved.

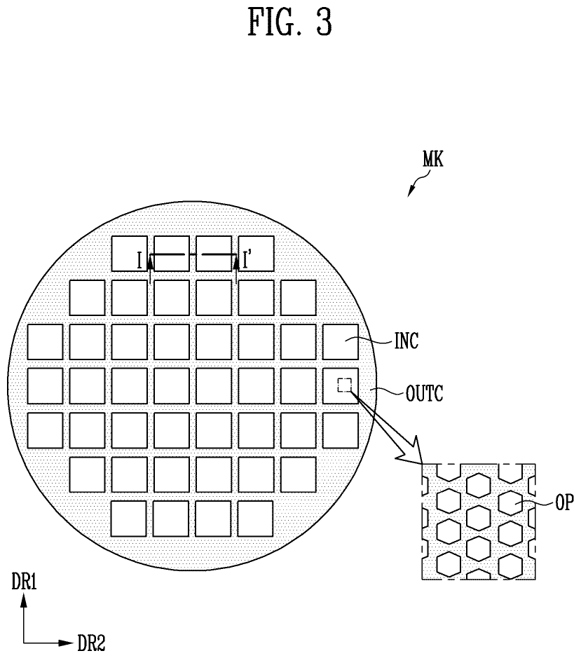

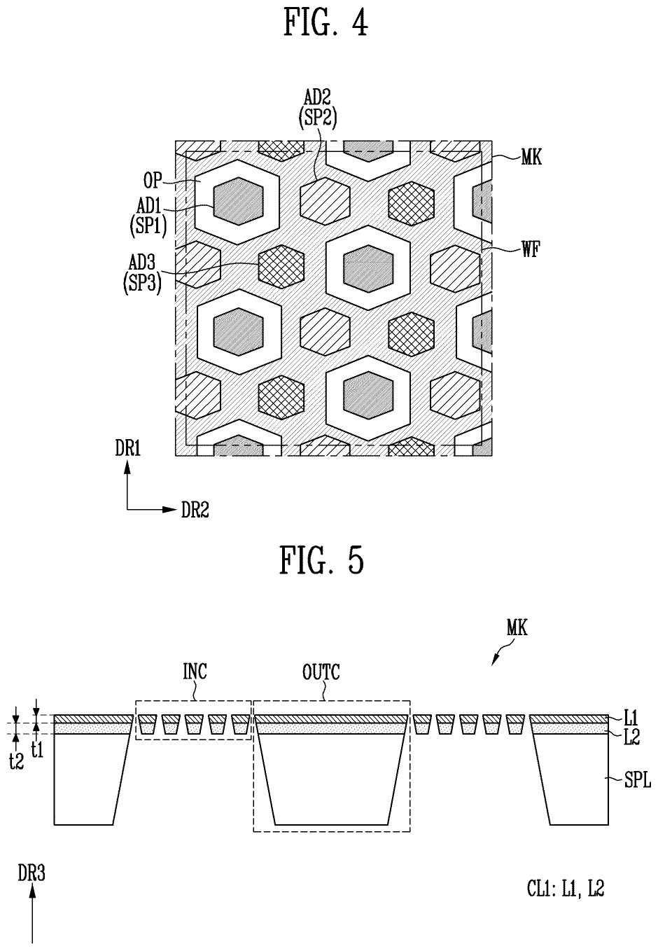

FIG. 3 is a plan view illustrating a mask according to one or more embodiments of the present disclosure. FIG. 4 is an enlarged view of an in-cell area of the mask. For convenience of description, anodes AD1 to AD3 of a wafer WF (see, e.g., FIGS. 1 and 2) are further illustrated. FIG. 5 is a cross-sectional view illustrating the mask of FIG. 3, according to one or more embodiments of the present disclosure. For example, FIG. 5 is a cross-sectional view taken along the line I-I′ of FIG. 3 which illustrates the mask MK, according to one or more embodiments of the present disclosure.

Referring to FIGS. 3 to 5, the mask MK may have a circular planar shape, but the present disclosure is not limited thereto. The planar shape of the mask MK may be changed in one or more suitable ways.

The mask MK may include an in-cell area INC (or a first area) and an out-cell area OUTC (or a second area) around the in-cell area INC.

The in-cell area INC may correspond to each cell (or an area to be separated into each display panel) of the wafer WF (see, e.g., FIGS. 1 and 2).

Openings OP passing through the mask MK may be formed in the in-cell area INC. A deposition material may not be blocked in (or may pass through) the openings OP in the in-cell area INC, and the deposition material may be deposited only on specific areas of the wafer WF aligned to face the openings OP. For example, referring to FIG. 4, the openings OP of the mask MK are aligned to face first anodes AD1 (or first subpixels SP1) of the wafer WF. In one or more embodiments, an emission layer of the first subpixel SP1 may be deposited only on the first anode AD1. Similarly, if (e.g., when) the openings OP of the mask MK are aligned to face second anodes AD2 of the wafer WF, an emission layer of a second subpixel SP2 may be deposited on the second anode AD2. If (e.g., when) the openings OP of the mask MK are aligned to face third anodes AD3 of the wafer WF, an emission layer of a third subpixel SP3 may be deposited on the third anode AD3.

Referring to FIG. 5, the mask MK may include a support layer SPL and a first composite layer CL1.

The support layer SPL may be arranged below the first composite layer CL1 (or on a lower surface of the first composite layer CL1) in the out-cell area OUTC. The support layer SPL may support the first composite layer CL1 and may impart deformation resistance (for example, resistance to deformation due to heat and/or deformation by an external force) to the first composite layer CL1. For example, the support layer SPL may include silicon. For example, the support layer SPL may include stainless steel, invar, nickel (Ni), cobalt (Co), a nickel alloy, a nickel-cobalt alloy, and/or the like which has a relatively low thermal expansion coefficient.

The first composite layer CL1 is arranged in the in-cell area INC and the out-cell area OUTC and may include a plurality of layers (or thin films). A thickness of the first composite layer CL1 in a third direction DR3 may be several μm, for example, in a range of about 1 μm to about 2 μm. In a range in which the thickness of the first composite layer CL1 is several μm, the number of the plurality of layers may be changed in one or more suitable ways. For example, the number of the plurality of layers may be in a range of 2 to 10, but the present disclosure is not limited thereto. On a plane normal (e.g., perpendicular) to the third direction DR3, the plurality of layers may have substantially the same area.

In one or more embodiments, the first composite layer CL1 may include one or more tensile layers (or first type or kind layers or first stress layers) and one or more compressive layers (or second type or kind layers or second stress layers). One or more tensile layers may include a tensile material of which stress is greater than 0, and one or more compressive layers may include a compressive material of which a stress is less than 0. For example, the tensile material may include at least one selected from among silicon nitride (SiNₓ, where 0<x≤2), molybdenum (Mo), and aluminum (Al). In a thin film state with a thickness of about 1 μm, the film stress of silicon nitride (SiNₓ) may be about 20 MPa, the film stress of molybdenum (Mo) may be about 1,125 MPa, and the film stress of aluminum (Al) may be about 96.6 MPa. For example, the compressive material may include at least one selected from among silicon oxide (SiOₓ, where 0<x≤2) and tungsten (W). In a thin film state, a film stress of silicon oxide (SiOₓ) may be about −180 MPa, and a film stress of tungsten (W) may be about −1,072 MPa. Stress is an inherent property of materials, and it is difficult to finely control the stress itself, and it is also difficult to manufacture a film with stress outside a specific range. For example, it is difficult to manufacture a layer with a compressive stress outside a range of 10 MPa to 300 MPa using silicon nitride (SiNₓ), and it is difficult to manufacture a layer with a tensile stress using silicon oxide (SiOₓ).

In one or more embodiments, a ratio between the total sum of the characteristic values (e.g., tensile or compressive forces) of the one or more tensile layers of the first composite layer CL1 and the total sum of the characteristic values (e.g., tensile or compressive forces) of the one or more compressive layers of the first composite layer CL1 may be in a range of about 0.5 to about 1. The characteristic value may be a value obtained by multiplying a stress of a corresponding layer by a thickness thereof.

In one or more embodiments, the total sum of the characteristic values of the one or more tensile layers of the first composite layer CL1 may be equal to the total sum of the characteristic values of the one or more compressive layers of the first composite layer CL1. In other words, the sum of the characteristic values (e.g., tensile and compressive forces) of the plurality of layers of the first composite layer CL1 may be substantially 0. The sum of the characteristic values may be represented by Equation 1.

$$\sum F = \sum σ \cdot t = 0 \qquad Equation 1$$

Here, F may be the characteristic value of each layer (or a thin film), for example, a tensile or compressive force occurring in each layer in a horizontal direction normal (e.g., perpendicular) to the third direction DR3, σ may be a stress of a corresponding layer, and t may be a thickness of the corresponding layer (that is, a thickness in the third direction DR3). Hereinafter, the term “characteristic value” will be represented by a “force” of a corresponding layer.

When the total sum of the forces of the plurality of layers is not 0 or is outside a reference range, a warpage (or deformation) may occur in the first composite layer CL1 (or the mask MK). In one or more embodiments, the first composite layer CL1 or the mask MK may be damaged due to the warpage, or the mask MK in which the warpage occurs may be misaligned with the wafer WF. Here, the reference range may correspond to a case in which a ratio of a force corresponding to a tensile force (that is, the total force of one or more tensile layers) to a force corresponding to a compressive force (that is, the total force of one or more compressive layers) among the forces of the plurality of layers is within a range of about 0.5 to about 1. Therefore, in embodiments, a force which is a key factor causing a warpage in the mask MK may be set to 0 or minimized or reduced to prevent damage and misalignment of the mask MK, wherein the force corresponds to the total amount of a tensile force and compressive force generated in each layer.

In one or more embodiments, the first composite layer CL1 may include a first layer L1 and a second layer L2. The second layer L2 may be arranged between the first layer L1 and the support layer SPL.

One of the first layer L1 or the second layer L2 may include a tensile material, and the other of the first layer L1 or the second layer L2 may include a compressive material. A ratio of a force of one of the first layer L1 or the second layer L2 to a force of the other of the first layer L1 or the second layer L2 may be within a range of about 0.5 to about 1. Here, the force of the first layer L1 may be a value obtained by multiplying a stress of the first layer L1 by a thickness t1 thereof, and the force of the second layer L2 may be a value obtained by multiplying a stress of the second layer L2 by a thickness t2 thereof. For example, a magnitude of the force of the first layer L1 may be equal to a magnitude of the force of the second layer L2. For example, the sum of the force of the first layer L1 and the force of the second layer L2 may be 0.

In one or more embodiments, the second layer L2 may include silicon nitride (SiNₓ), and the first layer L1 may include silicon oxide (SiOₓ). A film stress of silicon nitride (SiNₓ) may be about 20 MPa, and a film stress of silicon oxide (SiOₓ) may be about-180 MPa.

In such embodiments, for example, the thickness t2 of the second layer L2 including silicon nitride (SiNₓ) may be about 4.5 times to about 18 times the thickness t1 of the first layer L1 including silicon oxide (SiOₓ). For example, the thickness t1 of the first layer L1 may be about 0.05 times to about 0.22 times the thickness t2 of the second layer L2. For example, the thickness t1 of the first layer L1 may be within a range of about 0.05 μm to about 0.31 μm, and the thickness t2 of the second layer L2 may be within a range of about 1 μm to about 1.4 μm.

A ratio between the thickness t2 of the second layer L2 and the thickness t1 of the first layer L1, which minimizes the total force of the first layer L1 and the second layer L2, may be about 9:1. For example, the thickness t2 of the second layer L2 may be about 1.00 μm, and the thickness t1 of the first layer L1 may be about 0.11 μm. In such embodiments, the sum of the force of the second layer L2 (that is, 20 MPa×1 μm=20) and the force of the first layer L1 (that is, −180 MPa×0.11 μm=−20) may be 0. For example, the thickness t2 of the second layer L2 may be about 1.10 μm, and the thickness t1 of the first layer L1 may be about 0.122 μm. For example, the thickness t2 of the second layer L2 may be about 1.20 μm, and the thickness t1 of the first layer L1 may be about 0.133 μm. For example, the thickness t2 of the second layer L2 may be about 1.30 μm, and the thickness t1 of the first layer L1 may be about 0.144 μm. For example, the thickness t2 of the second layer L2 may be about 1.40 μm, and the thickness t1 of the first layer L1 may be about 0.155 μm. For example, the thickness t2 of the second layer L2 may be within a range of about 1 μm to about 1.4 μm, and the thickness t1 of the first layer L1 may be within a range of about 0.11 μm to about 0.15 μm.

Although it has been described that the second layer L2 includes silicon nitride (SiNₓ) and the first layer L1 includes silicon oxide (SiOₓ), the present disclosure is not limited thereto. For example, the first layer L1 may include silicon nitride (SiNₓ), and the second layer L2 may include silicon oxide (SiOₓ). In such embodiments, the thickness t1 of the first layer L1 including silicon nitride (SiNₓ) may be within a range of about 1 μm to about 1.4 μm, and the thickness t2 of the second layer L2 including silicon oxide (SiOₓ) may be within a range of about 0.11 μm to about 0.15 μm.

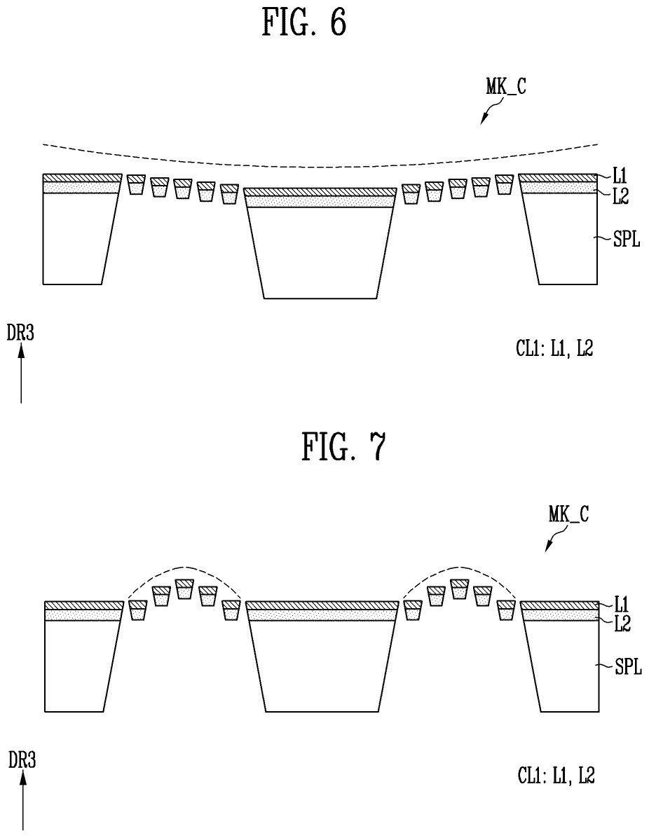

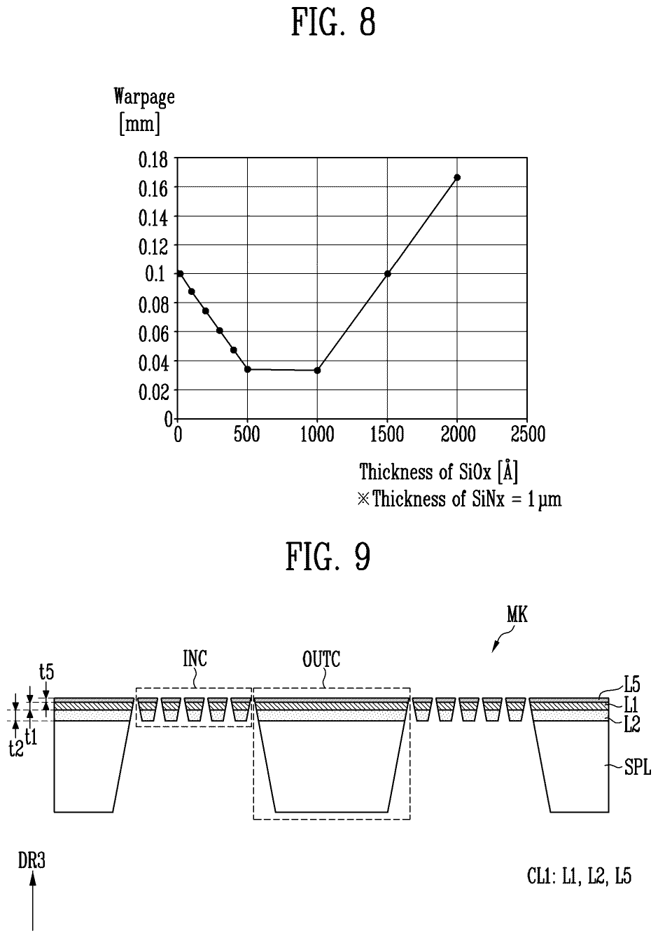

FIGS. 6 and 7 are each a cross-sectional view for describing warpage of a mask, according to one or more embodiments of the present disclosure. FIG. 8 is a graph showing warpage according to a thickness of a layer included in the mask of FIG. 5, according to embodiments of the present disclosure.

Referring to FIG. 6, a mask MK_C may be in a state of being placed on a flat plate. It is assumed that the total force (or the total sum of forces) of a first composite layer CL1 of the mask MK_C is not 0. Warpage will be described excluding a support layer SPL for imparting deformation resistance.

Warpage may occur in the mask MK_C due to a force of the first composite layer CL1. For example, if (e.g., when) a magnitude of a force (for example, a compressive force) of a first layer L1 of the first composite layer CL1 is smaller than a magnitude of a force (for example, a tensile force) of a second layer L2, an edge of the mask MK_C may rise higher than a central portion of the mask MK_C in a third direction DR3. In contrast, if (e.g., when) the magnitude of the force (for example, the compressive force) of the first layer L1 of the first composite layer CL1 is greater than the magnitude of the force (for example, the tensile force) of the second layer L2, the central portion of the mask MK_C may rise higher than the edge of the mask MK_C in the third direction DR3.

Referring to FIG. 7, the mask MK_C may be fixed by the second electrostatic chuck ESC2 and the magnetic plate MP of FIGS. 1 and 2. The mask MK_C may be in close contact with the wafer WF of FIG. 2 and thus may be substantially flat. However, warpage may occur in an in-cell area (or a membrane) of the mask MK_C due to the force of the first composite layer CL1. For example, if (e.g., when) the magnitude of the force of the first layer L1 is greater than the magnitude of the force of the second layer L2, the in-cell area of the mask MK_C may be warped to protrude in the third direction DR3. In some cases, the in-cell area of the mask MK_C may protrude by about 100 μm to about 200 μm in the third direction DR3.

In a process of unfolding the mask MK_C from a state of FIG. 6 to a state of FIG. 7, the mask MK_C may be damaged. For example, the mask MK_C in which a lot of warpage occurs in FIG. 6 or 7 may be damaged.

In one or more embodiments, even if the mask MK_C is not damaged, because the in-cell area is in a state of being warped, the mask MK_C may be misaligned with the wafer WF. Referring to FIG. 4, for example, although an opening OP of the mask MK_C is aligned with a first anode AD1 in a portion of the in-cell area, the opening OP may be warped from the first anode electrode AD1 in a first direction DR1 and/or a second direction DR2 in the remainder of the in-cell area. In such cases, an emission layer may not be deposited properly, and defects may occur in a display panel.

Accordingly, the mask MK according to one or more embodiments may include the first composite layer CL1 in which the total force is minimized or reduced, and thus damage and misalignment of the mask MK may be prevented or reduced.

Referring to FIGS. 5 and 8, a thickness of a layer including silicon nitride (SiNₓ) which is a tensile material, for example, the thickness t2 of the second layer L2 of FIG. 5, is fixed to 1 μm. As a thickness of a layer including silicon oxide (SiOₓ) which is a compressive material, for example, the thickness t1 of the first layer L1 of FIG. 5 is changed between 0 Å and 2,000 Å, a degree of a warpage of the mask MK may also be changed. The degree of the warpage of the mask MK indicates a distance by which the mask MK protrudes in the third direction DR3 or in a direction opposite to the third direction DR3 in FIG. 6.

When the thickness of the layer including silicon oxide (SiOₓ) was 0, that is, if (e.g., when) the first composite layer CL1 included only the layer including silicon nitride (SiNₓ), a warpage of about 0.1 mm occurred in the mask MK (see, e.g., FIG. 8).

When the thickness of the layer including silicon oxide (SiOₓ) was increased to 500 Å, a warpage of the mask MK was reduced to about 0.035 mm (see, e.g., FIG. 8). A compressive force of a layer including silicon oxide (SiOₓ) with a thickness of 500 Å may be about −9 (−180 MPa×0.05 μm) and may be about 45% of a tensile force (for example, 20 MPa×1 μm=20) of a layer including silicon nitride (SiNₓ) with a thickness of 1 μm.

When the thickness of the layer including silicon oxide (SiOₓ) was 1,000 Å, a warpage of the mask MK was reduced to about 0.03 mm (see, e.g., FIG. 8). In a section in which the thickness of the layer including silicon oxide (SiOₓ) was in a range of 500 Å to 1,000 Å, a warpage of the mask MK was minimized or reduced. When the thickness of the layer including silicon oxide (SiOₓ) was increased to 2,000 Å, a warpage of the mask MK increased to about 0.17 mm (see, e.g., FIG. 8). In the corresponding section, unlike the mask MK_C shown in FIG. 6, a warpage occurred in a direction opposite to the third direction DR3.

When a tensile force of a layer including silicon nitride (SiNₓ) with a thickness of 1 μm is 20 (that is, 20 MPa×1 μm), a thickness of silicon oxide (SiOₓ), which has a compressive force that is 50% of a tensile force, may be about 0.055 μm (that is, 10/−180 MPa), and a thickness of silicon oxide (SiOₓ), which has a compressive force that is 100% of a tensile force, may be about 0.11 μm (for example, 20/−180 MPa). For example, it was confirmed that if (e.g., when) a ratio of a force of the layer including silicon nitride (SiNₓ) to a force of the layer including silicon oxide (SiOₓ) was in a range of about 0.5 to about 1, a warpage of the mask MK was minimized or reduced.

FIG. 9 is a cross-sectional view illustrating the mask of FIG. 3, according to one or more embodiments of the present disclosure.

Referring to FIG. 9, the first composite layer CL1 of the mask MK may include three layers L1, L2, and L5. As compared to one or more embodiments of FIG. 5, the mask MK may further include a fifth layer L5. Except for the fifth layer L5, the embodiments of FIG. 9 are substantially the same as or similar to the embodiments of FIG. 5, and thus redundant descriptions may not be provided.

The fifth layer L5 may be arranged on the first layer L1.

In one or more embodiments, one of the first layer L1, the second layer L2, or the fifth layer L5 may include a different material from the remainder of the first layer L1, the second layer L2, and the fifth layer L5. For example, one of the first layer L1, the second layer L2, or the fifth layer L5 may include a tensile material (or a compressive material), and the remainder of the first layer L1, the second layer L2, and the fifth layer L5 may include a compressive material (or a tensile material).

In one or more embodiments, the second layer L2 and the fifth layer L5 may include a tensile material, and the first layer L1 may include a compressive material. A ratio of the total force of the second layer L2 and the fifth layer L5 to a force of the first layer L1 may be within a range of about 0.5 to about 1. Here, the force of the fifth layer L5 may be a value obtained by multiplying a stress of the fifth layer L5 and a thickness t5 thereof. For example, a magnitude of the total force of the second layer L2 and the fifth layer L5 may be equal to a magnitude of the force of the first layer L1. For example, the sum of the total force of the second layer L2 and the fifth layer L5 and the force of the first layer L1 may be 0.

In one or more embodiments, the second layer L2 and the fifth layer L5 may include silicon nitride (SiNₓ), and the first layer L1 may include silicon oxide (SiOₓ). A film stress of silicon nitride (SiNₓ) may be about 20 MPa, and a film stress of silicon oxide (SiOₓ) may be about −180 MPa.

In such embodiments, for example, the sum of the thickness t2 of the second layer L2 and the thickness t5 of the fifth layer L5 may be about 4.5 times to about 18 times the thickness t1 of the first layer L1. For example, the thickness t1 of the first layer L1 may be about 0.05 times to about 0.22 times the sum of the thickness t2 of the second layer L2 and the thickness t5 of the fifth layer L5. For example, the thickness t1 of the first layer L1 may be within a range of about 0.05 μm to about 0.31 μm, the thickness t2 of the second layer L2 and the thickness t5 of the fifth layer L5 may be within a range of about 1 μm to about 1.4 μm.

For example, the thickness t2 of the second layer L2 and the thickness t5 of the fifth layer L5 may each be about 0.50 μm, and the thickness t1 of the first layer L1 may be about 0.11 μm. In such embodiments, the total sum of a force of the first layer L1 (that is, −180 MPa×0.11 μm=−20), a force of the second layer L2 (that is, 20 MPa×0.5 μm=10), and the force of the fifth layer L5 (for example, 20 MPa×0.5 μm=10) may be 0. For example, the thickness t2 of the second layer L2 and the thickness t5 of the fifth layer L5 may each be about 0.55 μm, and the thickness t1 of the first layer L1 may be about 0.122 μm. For example, the thickness t2 of the second layer L2 and the thickness t5 of the fifth layer L5 may each be about 0.60 μm, and the thickness t1 of the first layer L1 may be about 0.33 μm. For example, the thickness t2 of the second layer L2 and the thickness t5 of the fifth layer L5 may each be about 0.65 μm, and the thickness t1 of the first layer L1 may be about 0.144 μm. For example, the thickness t2 of the second layer L2 and the thickness t5 of the fifth layer L5 may each be about 0.70 μm, and the thickness t1 of the first layer L1 may be about 0.155 μm. For example, the thickness t2 of the second layer L2 and the thickness t5 of the fifth layer L5 may each be within a range of about 0.5 μm to about 0.7 μm, and the thickness of the first layer L1 may be within a range of about 0.11 μm to about 0.15 μm.

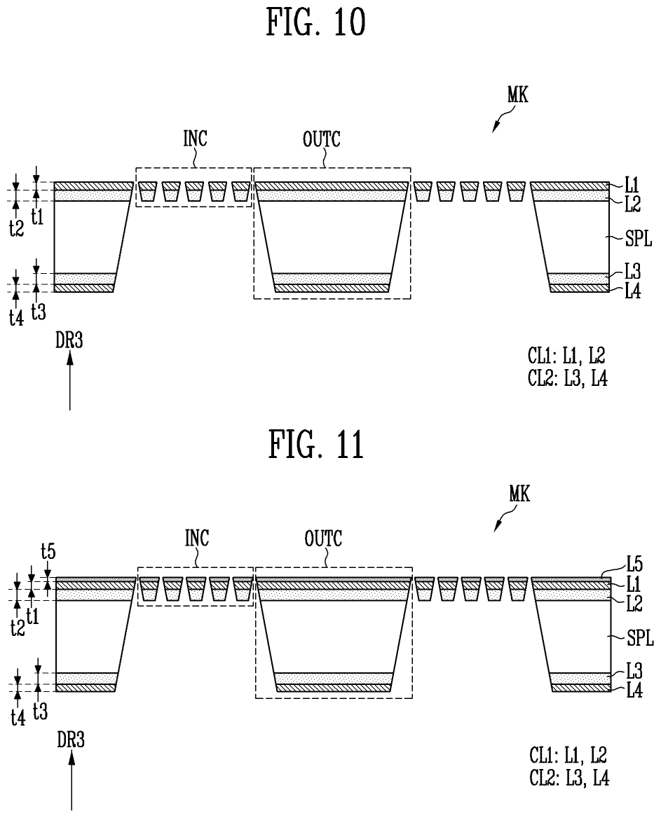

FIG. 10 is a cross-sectional view illustrating the mask of FIG. 3, according to one or more embodiments of the present disclosure.

Referring to FIGS. 5 and 10, the mask MK may further include a second composite layer CL2. Except for the second composite layer CL2, the embodiments of FIG. 10 are substantially the same as or similar to the embodiments of FIG. 5, and thus redundant descriptions may not be provided. When deposition (that is, single side deposition) is performed only on an upper surface of the support layer SPL through plasma enhanced chemical vapor deposition (PECVD), the mask MK according to one or more embodiments of FIG. 5 may be formed, and if (e.g., when) deposition (that is, double-side deposition) is performed on upper and lower surfaces of the support layer SPL through low pressure chemical vapor deposition (LPCVD), the mask MK according to one or more embodiments of FIG. 10 may be formed.

The second composite layer CL2 is arranged below (or on the lower surface of) the support layer SPL in the out-cell area OUTC and may include a plurality of layers (or thin films). A thickness of the second composite layer CL2 in the third direction DR3 may be several μm, for example, within a range of about 1 μm to about 2 μm. Similarly to the first composite layer CL1, the number of layers of the second composite layer CL2 may be variously changed within a range in which the thickness of the second composite layer CL2 is several μm. For example, the number of layers of the second composite layer CL2 may be in a range of 2 to 10, but the present disclosure is not limited thereto. Even if (e.g., when) the first composite layer CL1 and the second composite layer CL2 are deposited concurrently (e.g., simultaneously) on both surfaces (e.g., opposite surfaces) of the support layer SPL, through surface treatment of one surface of the support layer SPL, the number and thickness of layers of the first composite layer CL1 may be different from the number and thickness of layers of the second composite layer CL2. On a plane normal (e.g., perpendicular) to the third direction DR3, the plurality of layers of the second composite layer CL2 may have substantially the same area.

In one or more embodiments, the second composite layer CL2 may include one or more tensile layers and one or more compressive layers.

In one or more embodiments, forces (or characteristic values) of the plurality of layers of the first composite layer CL1 may equal to forces of the plurality of layers of the second composite layer CL2. In such embodiments, similar to the first composite layer CL1, a ratio between the total sum of forces (or characteristic values) of one or more tensile layers of the second composite layer CL2 and the total sum of forces of one or more compressive layers of the second composite layer CL2 may be within a range from about 0.5 to about 1.

In one or more embodiments, the second composite layer CL2 may include a third layer L3 and a fourth layer L4. The third layer L3 and the fourth layer L4 may be sequentially arranged on the lower surface of the support layer SPL. The third layer L3 may be arranged between the support layer SPL and the fourth layer L4.

One of the third layer L3 or the fourth layer L4 may include a tensile material, and the other of the third layer L3 or the fourth layer L4 may include a compressive material.

In one or more embodiments, the first layer L1 and the fourth layer L4 may include the same material, and the second layer L2 and the third layer L3 may include the same material. For example, the first layer L1 and the fourth layer L4 may include silicon oxide (SiOₓ), and the second layer L2 and the third layer L3 may include silicon nitride (SiNₓ). In one or more embodiments, the total force of the first composite layer CL1 and the second composite layer CL2 may be represented by Equation 2.

$${σ}_{1} ( t 1 - t 4 ) + {σ}_{2} ( t 2 - t 3 ) = 0 \qquad Equation 2$$

Here, σ₁ may be a stress of the first layer L1 and the fourth layer L4, σ₂ may be a stress of the second layer L2 and the third layer L3, and t1, t2, t3, and t4 may be thicknesses of the first layer L1, the second layer L2, the third layer L3, and the fourth layer L4, respectively.

The first composite layer CL1 and the second composite layer CL2 may be arranged on different surfaces of the support layer SPL and may affect a warpage of the mask MK in different directions. Accordingly, if (e.g., when) the total force of the first composite layer CL1 is equal to the total force of the second composite layer CL2, a warpage of the mask MK (for example, a warpage in the out-cell area OUTC) may be minimized or reduced. For example, the first composite layer CL1 and the second composite layer CL2 may have a structure that is symmetrical with respect to the support layer SPL. For example, the thickness t1 of the first layer L1 may be equal to the thickness t4 of the fourth layer L4, and the thickness t2 of the second layer L2 may be equal to the thickness t3 of the third layer L3. Examples of the thickness of each of the first layer L1 and the second layer L2 have been described with reference to FIG. 5. For example, the thickness t3 of the third layer L3 including silicon nitride (SiNₓ) may be within a range of about 1 μm to about 1.4 μm, and the thickness t4 of the fourth layer L4 including silicon oxide (SiOₓ) may be within a range of about 0.11 μm to about 0.15 μm.

FIG. 11 is a cross-sectional view illustrating the mask of FIG. 3, according to one or more embodiments of the present disclosure.

Referring to FIGS. 9 and 11, the mask MK may further include a second composite layer CL2. Except for the second composite layer CL2, the embodiments of FIG. 11 may be substantially the same as or similar to the embodiments of FIG. 9. In addition, the second composite layer CL2 of FIG. 11 may be similar to the second composite layer CL2 of FIG. 10. Therefore, redundant descriptions may not be provided.

In one or more embodiments, forces (or characteristic values) of the plurality of layers of the first composite layer CL1 may equal to forces of the plurality of layers of the second composite layer CL2. This may be represented by Equation 3.

$${σ}_{1} \cdot t 1 + {σ}_{2} \cdot t 2 = {σ}_{3} \cdot t 3 + {σ}_{4} \cdot t 4 + {σ}_{5} \cdot t 5 \qquad Equation 3$$

Here, σ₁, σ₂, σ₃, σ₄, and σ₅ may be stresses of the first layer L1, the second layer L2, the third layer L3, the fourth layer L4, and the fifth layer L5, respectively, and t1, t2, t3, t4, and t5 may be thicknesses of the first layer L1, the second layer L2, the third layer L3, the fourth layer L4, and the fifth layer L5, respectively.

For example, if (e.g., when) the first layer L1 and the fourth layer L4 include the same material, and the second layer L2, the third layer L3, and the fifth layer L5 include the same material, the total force of the first composite layer CL1 and the second composite layer CL2 may be represented by “σ1(t1+t5−t4)+σ2(t2−t3)=0.”

Examples of the thickness of each of the first layer L1, the second layer L2, and the fifth layer L5 have been described with reference to FIG. 9. In addition, examples of the thickness of each of the third layer L3 and fourth layer L4 have been described with reference to FIG. 10. Therefore, examples of the thickness of each layer may not be repeated.

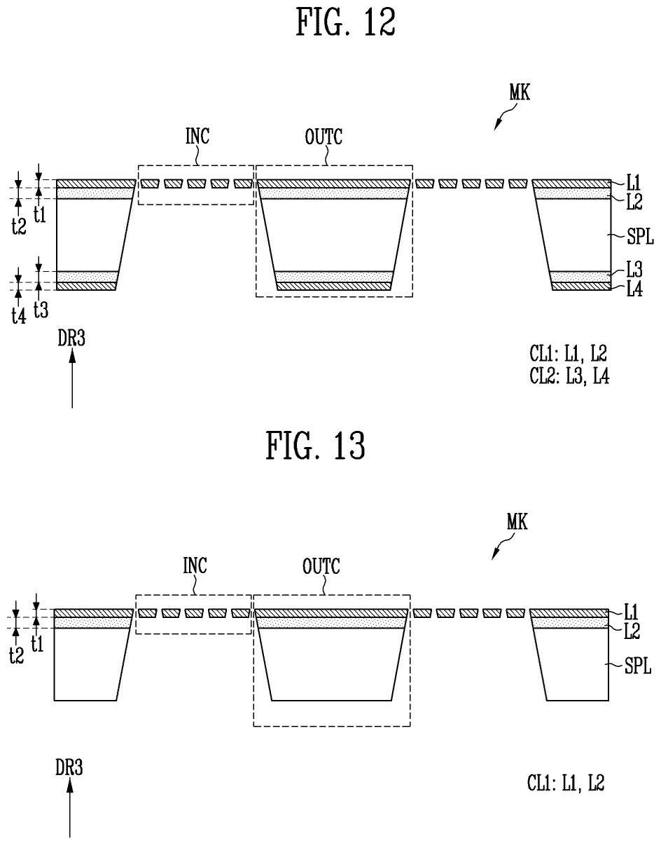

FIG. 12 is a cross-sectional view illustrating the mask of FIG. 3, according to one or more embodiments of the present disclosure.

Referring to FIGS. 10 and 12, the embodiments of FIG. 12 may be substantially the same as or similar to the embodiments of FIG. 10, except that only a single layer is arranged in the in-cell area INC. Therefore, redundant descriptions may not be provided.

The first layer L1 among the plurality of layers of the first composite layer CL1 may be arranged in the in-cell area INC. A force and a warpage (or deformation) according to the force in the in-cell area INC may be determined by the first layer L1. Therefore, a ratio between a force (and a thickness) of the first layer L1 and a force (and a thickness) of the second layer L2 is not particularly limited, and a thickness t1 of the first layer L1 including a material with low stress may be minimized or reduced to minimize or reduce the warpage of the in-cell area INC. For example, the first layer L1 may include silicon nitride (SiNₓ) which has relatively low stress.

In one or more embodiments, a force in the out-cell area OUTC may be determined by both of the first composite layer CL1 and the second composite layer CL2.

In one or more embodiments, the first composite layer CL1 and the second composite layer CL2 may have a structure that is symmetrical with respect to the support layer SPL. In such embodiments, a warpage in the out-cell area OUTC may be minimized or reduced.

In one or more embodiments, the first layer L1 and the fourth layer L4 may include the same material, and the second layer L2 and the third layer L3 may include the same material. For example, the first layer L1 and the fourth layer L4 may include silicon nitride (SiNₓ), and the second layer L2 and the third layer L3 may include silicon oxide (SiOₓ). In one or more embodiments, the total force of the first composite layer CL1 and the second composite layer CL2 may be represented by Equation 2 described above.

For example, the thickness t1 of the first layer L1 may be equal to the thickness t4 of the fourth layer L4, and the thickness t2 of the second layer L2 may be equal to the thickness t3 of the third layer L3. Examples of the thickness of each of the first layer L1 and the second layer L2 has been described with reference to FIG. 5. Because the thickness of each of the third layer L3 and the fourth layer L4 may be equal to the thickness of one of the second layer L2 or the first layer L1, examples of the thickness of each layer may not be repeated.

FIG. 13 is a cross-sectional view illustrating the mask of FIG. 3, according to one or more embodiments of the present disclosure.

Referring to FIGS. 5 and 13, the embodiments of FIG. 13 may be substantially the same or similar to the embodiments of FIG. 5, except that only a single layer is arranged in the in-cell area INC. Therefore, redundant descriptions may not be provided.

The first layer L1 among the plurality of layers of the first composite layer CL1 may be arranged in the in-cell area INC. A force and a warpage (or deformation) according to the force in the in-cell area INC may be determined by the first layer L1. Accordingly, a thickness t1 of the first layer L1 including a material with low stress may be minimized or reduced to minimize or reduce a warpage of the in-cell area INC.

A force in the out-cell area OUTC may be determined by the first composite layer CL1. As described with reference to FIG. 5, a ratio between the total force of one or more tensile layers of the first composite layer CL1 and the total force of one or more compressive layers of the first composite layer CL1 may be within a range of about 0.5 to about 1. For example, the total sum of the characteristic values of one or more tensile layers of the first composite layer CL1 may be equal to the total sum of the characteristic values of one or more compressive layers of the first composite layer CL1. For example, the total sum of the characteristic values (or tensile and compressive forces) of a plurality of layers of the first composite layer CL1 may be substantially 0. In such embodiments, a warpage of the out-cell area OUTC may be minimized or reduced.

In one or more embodiments, the first composite layer CL1 may include the first layer L1 and the second layer L2. One of the first layer L1 or the second layer L2 may include a tensile material, and the other of the first layer L1 or the second layer L2 may include a compressive material. For example, the second layer L2 may include silicon nitride (SiNₓ), and the first layer L1 may include silicon oxide (SiOₓ).

Because examples of a thickness of each of the first layer L1 and the second layer L2 have been described with reference to FIG. 5, examples of the thickness of each layer may not be repeated.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value. Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A deposition mask for depositing a pattern on a display panel, the deposition mask comprising:
an in-cell area and an out-cell area around the in-cell area, wherein the deposition mask has an opening in the in-cell area;
a first composite layer in the in-cell area and the out-cell area; and
a support layer on a lower surface of the first composite layer in the out-cell area,
wherein the first composite layer comprises one or more tensile layers comprising a tensile material that has a stress greater than 0, and comprises one or more compressive layers comprising a compressive material that has a stress less than 0,
wherein each layer of the one or more tensile layers and the one or more compressive layers has a characteristic value measured by multiplying a stress of each layer by a corresponding thickness of each layer, and
wherein a ratio between a total sum of the characteristic values of the one or more tensile layers of the first composite layer and a total sum of the characteristic values of the one or more compressive layers of the first composite layer is within a range of about 0.5 to about 1.

2. The deposition mask of claim 1, wherein the tensile material comprises at least one selected from among silicon nitride, molybdenum, and aluminum, and
wherein the compressive material comprises at least one selected from among silicon oxide and tungsten.

3. The deposition mask of claim 1, wherein the total sum of the characteristic values of the one or more tensile layers is equal to the total sum of the characteristic values of the one or more compressive layers.

4. The deposition mask of claim 1, wherein the first composite layer comprises a first layer and a second layer between the first layer and the support layer,
wherein the one or more tensile layers comprise one of the first layer or the second layer, and the one or more compressive layers comprise the other of the first layer or the second layer, and
wherein a ratio between a characteristic value of a first layer and a characteristic value of the second layer is within a range of about 0.5 to about 1, and
wherein the characteristic value of the first layer is measured by multiplying a stress of the first layer by a thickness of the first layer, and the characteristic value of the second layer is measured by multiplying a stress of the second layer by a thickness of the second layer.

5. The deposition mask of claim 4, wherein one of the first layer or the second layer comprises silicon nitride, and the other of the first layer or the second layer comprises silicon oxide, and
wherein the thickness of one of the first layer or the second layer is about 4.5 times to about 18 times the thickness of the other of the first layer or the second layer.

6. The deposition mask of claim 5, wherein the thickness of one of the first layer or the second layer is within a range of about 1 μm to about 1.4 μm, and
wherein the thickness of the other of the first layer or the second layer is within a range of about 0.05 μm to about 0.31 μm.

7. The deposition mask of claim 5, wherein the thickness of one of the first layer or the second layer is within a range of about 1 μm to about 1.4 μm, and
wherein the thickness of the other of the first layer or the second layer is within a range of about 0.11 μm to about 0.15 μm.

8. The deposition mask of claim 1, wherein the first composite layer comprises a first layer, a second layer between the first layer and the support layer, and a third layer on the first layer,
wherein the one or more tensile layers comprise the second layer or the third layer, and the one or more compressive layers comprises the first layer, and
wherein a ratio between a total sum of characteristic values of the second layer and the third layer and a characteristic value of the first layer is within a range of about 0.5 to about 1, and
wherein the characteristic value of the first layer is measured by multiplying a stress of the first layer by a thickness of the first layer, the characteristic value of the second layer is measured by multiplying a stress of the second layer by a thickness of the second layer, and the characteristic value of the third layer is measured by multiplying a stress of the third layer by a thickness of the third layer.

9. The deposition mask of claim 8, wherein the second layer and the third layer comprise silicon nitride, and the first layer comprises silicon oxide, and
wherein a total thickness of the second layer and the third layer is about 4.5 times to about 18 times the thickness of the first layer.

10. The deposition mask of claim 9, wherein the thickness of each of the second layer and the third layer is within a range of about 0.5 μm to about 0.7 μm, and
wherein the thickness of the first layer is within a range of about 0.1 μm to about 0.17 μm.

11. The deposition mask of claim 1, further comprising a second composite layer on a lower surface of the support layer,
wherein the first composite layer and the second composite layer have a structure that is symmetrical with respect to the support layer.

12. The deposition mask of claim 11, wherein the first composite layer comprises a first layer and a second layer between the first layer and the support layer,
wherein the second composite layer comprises a fourth layer and a third layer between the fourth layer and the support layer,
wherein the one or more tensile layers comprise one of the first layer or the second layer and one of the third layer or the fourth layer, the one or more compressive layers comprise the other of the first layer or the second layer, and the other of the third layer or the fourth layer,
wherein a total sum of characteristic values of the first layer and the second layer is equal to a total sum of characteristic values of the third layer and the fourth layer, and
wherein the characteristic value of the first layer is measured by multiplying a stress of the first layer by a thickness of the first layer, the characteristic value of the second layer is measured by multiplying a stress of the second layer by a thickness of the second layer, the characteristic value of the third layer is measured by multiplying a stress of the third layer by a thickness of the third layer, and the characteristic value of the fourth layer is measured by multiplying a stress of the fourth layer by a thickness of the fourth layer.

13. The deposition mask of claim 12, wherein the first layer and the fourth layer comprise the same material, and the second layer and the third layer comprise the same material.

14. The deposition mask of claim 13, wherein the thickness of the first layer is equal to the thickness of the fourth layer, and the thickness of the second layer is equal to the thickness of the third layer.

15. A deposition mask for depositing a pattern on a display panel, the deposition mask comprising:
an in-cell area and an out-cell area around the in-cell area;
a support layer in the out-cell area;
a first composite layer on the support layer and comprising a plurality of layers, wherein one of the plurality of layers is in the in-cell area; and
a second composite layer below the support layer and comprising a plurality of layers,
wherein, in the in-cell area, the first composite layer has an opening corresponding to a pixel of the display panel, and
wherein the first composite layer and the second composite layer have a structure that is symmetrical with respect to the support layer.

16. The deposition mask of claim 15, wherein some of the plurality of layers of each of the first composite layer and the second composite layer comprise a tensile material having a stress greater than 0, and
wherein others of the plurality of layers of each of the first composite layer and the second composite layer comprise a compressive material having a stress less than 0.

17. The deposition mask of claim 16, wherein the tensile material comprises at least one selected from among silicon nitride, molybdenum, and aluminum, and
wherein the compressive material comprises at least one selected from among silicon oxide and tungsten.

18. The deposition mask of claim 15, wherein the first composite layer comprises a first layer and a second layer between the first layer and the support layer,
wherein the second composite layer comprises a fourth layer and a third layer between the fourth layer and the support layer,
wherein a sum of a characteristic value of the first layer and a characteristic value of the second layer is equal to a sum of a characteristic value of the third layer and a characteristic value of the fourth layer, and
wherein the characteristic value of the first layer is measured by multiplying a stress of the first layer by a thickness of the first layer, the characteristic value of the second layer is measured by multiplying a stress of the second layer by a thickness of the second layer, the characteristic value of the third layer is measured by multiplying a stress of the third layer by a thickness of the third layer, and the characteristic value of the fourth layer is measured by multiplying a stress of the fourth layer by a thickness of the fourth layer.

19. The deposition mask of claim 18, wherein the first layer and the fourth layer comprise the same material, and the second layer and the third layer comprise the same material.

20. The deposition mask of claim 19, wherein the thickness of the first layer is equal to the thickness of the fourth layer, and the thickness of the second layer is equal to the thickness of the third layer.
